(19) United States
(12) Patent Application Publication
(10) Pub. No.: US 2007/0004066 A1
(43) Pub. Date: Jan. 4, 2007

(54) Method for manufacturing a light emitting device and a light emitting device manufactured therefrom

(76) Inventors: Dong-Sing Wuu, Taichung City (TW); Ray-Hua Horng, Taichung City (TW)

Correspondence Address: FOLEY AND LARDNER LLP;SUITE 500, 3000 K STREET NW, WASHINGTON, DC, 20007, US

(21) Appl. No.: 11/171,339

(22) Filed: Jul. 1, 2005

(51) Int. Cl. H01L 21/00

(52) U.S. Cl. 438/29

(57) ABSTRACT

A method for manufacturing a light emitting device includes: preparing a light emitting diode including an epitaxial substrate, an n-type cladding layer, an active layer, a p-type cladding layer, and first and second electrodes; thinning the epitaxial substrate; and forming a reflecting layer and a heat dissipating substrate on the thinned epitaxial substrate. A light emitting device manufactured from the above method is also disclosed.

### BACKGROUND OF THE INVENTION

1. Field of the Invention

This invention relates to a method for making a light emitting device, more particularly to a method for manufacturing a light emitting device including a reflecting layer and a heat dissipating substrate, and to a light emitting device manufactured therefrom.

2. Description of the Related Art

Conventional light emitting diodes, such as the light emitting diode 1 of gallium nitride series shown in FIG. 1, include an epitaxial substrate 11 made from sapphire, and a light emitting unit 12 formed on the epitaxial substrate 11 by epitaxial crystal-growth techniques, so as to provide good quality of the grown epitaxial crystals.

The light emitting unit 12 includes an n-type cladding layer 121 formed on the epitaxial substrate 11, an active layer 122 formed on the n-type cladding layer 121, a p-type cladding layer 123 formed on the active layer 122, a transparent conductive layer 124 formed on the p-type cladding layer 123, and a p-type ohmic electrode 125 and an n-type ohmic electrode 126 formed on the transparent conductive layer 124 and the n-type cladding layer 121, respectively.

When a proper voltage is applied to the light emitting unit 12, a current uniformly flows from the p-type ohmic electrode 125, through the transparent conductive layer 124, the p-type cladding layer 123, the active layer 122, and the n-type cladding layer 121, to the n-type ohmic electrode 126. When the current flows through the active layer 122, the active layer 122 is activated to produce a plurality of protons, thereby emitting light beams.

The abovementioned light emitting diode 1 has advantages of low power consumption, low driving voltage, high output power, and high resolution, and can be used in various applications, such as displays and traffic lights. However, for the light emitting diode 1 of gallium nitride series, the substrate 11 currently suitable for growing epitaxial crystals is restricted to the sapphire substrate, which has a poor heat dissipating ability. Therefore, there is still a need in the art to provide a light emitting diode which not only has the aforesaid advantages of the conventional light emitting diode but also has a relatively good heat dissipating ability.

### SUMMARY OF THE INVENTION

Therefore, the object of the present invention is to provide a method for manufacturing a light emitting device and a light emitting device made therefrom that are clear of the aforesaid drawback of the prior art.

According to one aspect of this invention, a method for manufacturing a light emitting device includes the steps of: (a) preparing a light emitting diode including an epitaxial substrate having a top surface and a bottom surface opposite to the top surface, an n-type cladding layer formed on the top surface of the epitaxial substrate, an active layer formed on the n-type cladding layer, a p-type cladding layer formed on the active layer, and first and second electrodes formed on the n-type and p-type cladding layers, respectively; (b) thinning the epitaxial substrate from the bottom surface of the epitaxial substrate; (c) forming a reflecting layer on the bottom surface of the thinned epitaxial substrate; and (d) forming a heat dissipating substrate, which has a thermal conductivity higher than that of the epitaxial substrate, on the reflecting layer.

According to another aspect of this invention, a method for manufacturing a light emitting device includes the steps of: (a) preparing a light emitting diode including an epitaxial substrate having a top surface and a bottom surface opposite to the top surface, an n-type cladding layer formed on the top surface of the epitaxial substrate, an active layer formed on the n-type cladding layer, a p-type cladding layer formed on the active layer, and first and second electrodes formed on the n-type and p-type cladding layers, respectively; (b) thinning the epitaxial substrate from the bottom surface of the epitaxial substrate; (c) forming a heat dissipating unit including a heat dissipating substrate that has a thermal conductivity higher than that of the epitaxial substrate, and a reflecting layer that is bonded to the heat dissipating substrate; and (d) bonding the reflecting layer of the heat dissipating unit to the epitaxial substrate of the light emitting diode.

According to yet another aspect of this invention, a light emitting device includes: a heat dissipating substrate; a reflecting layer bonded to the heat dissipating substrate; a light emitting diode bonded to the reflecting layer, the light emitting diode including an epitaxial substrate having a top surface and a bottom surface opposite to the top surface, an n-type cladding layer formed on the top surface of the epitaxial substrate, an active layer formed on the n-type cladding layer, a p-type cladding layer formed on the active layer, and first and second electrodes formed on the n-type and p-type cladding layers, respectively.

The reflecting layer is bonded to the bottom surface of the epitaxial substrate. The heat dissipating substrate has a thermal conductivity higher than that of the epitaxial substrate.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a schematic view to illustrate a conventional light emitting diode;

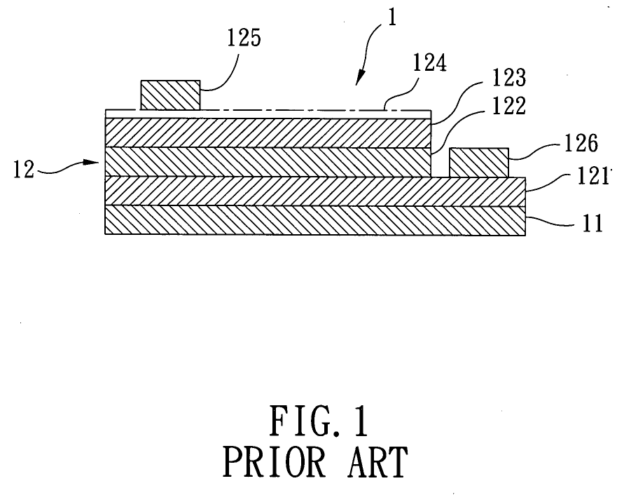

FIG. 2 is a flowchart to illustrate consecutive steps of the first preferred embodiment of a method for manufacturing a light emitting device according to this invention;

FIG. 3 is a schematic view to illustrate the first preferred embodiment of a light emitting device made from the method illustrated in FIG. 2;

FIG. 4 is a flow chart to illustrate consecutive steps of the second preferred embodiment of a method for manufacturing a light emitting device according to this invention;

FIG. 5 is a schematic view to illustrate the second preferred embodiment of a light emitting device made from the method illustrated in FIG. 4;

FIG. 6 is a schematic view to illustrate a structural modification of the light emitting device shown in FIG. 3; and

FIG. 7 is a schematic view to illustrate a structural modification of the light emitting device shown in FIG. 5.

### DETAILED DESCRIPTION OF THE PREFERRED EMBODIMENTS

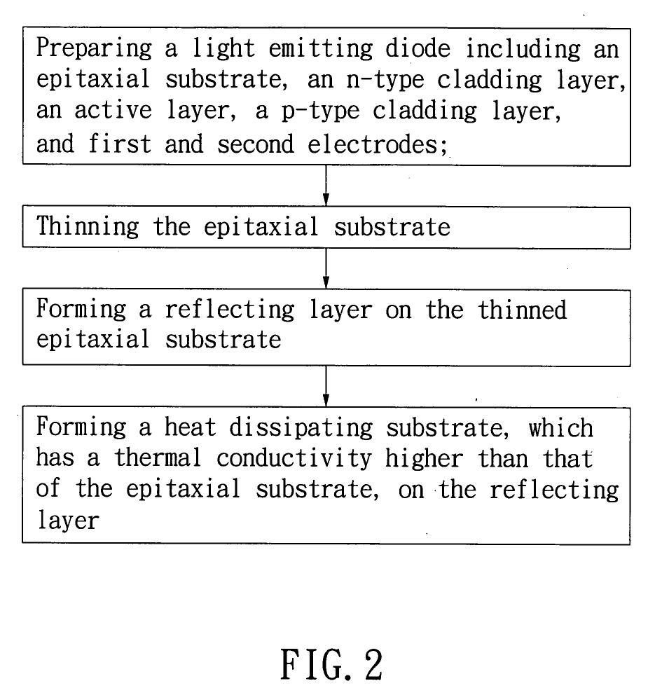

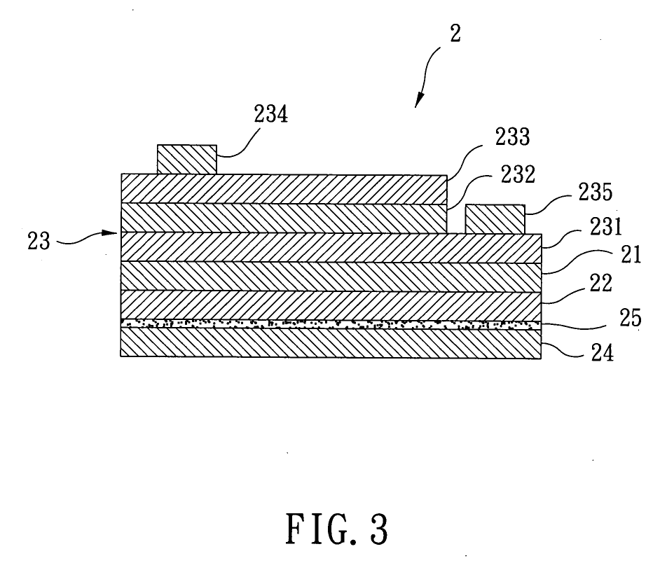

FIGS. 2 and 3 illustrate the first preferred embodiment of the method for manufacturing a light emitting device and the light emitting device thus formed. In the first preferred embodiment, the light emitting device 2 is manufactured by first preparing a light emitting diode. The light emitting diode is prepared using conventional epitaxial crystal techniques, and includes an epitaxial substrate 21 having a top surface and a bottom surface opposite to the top surface, an n-type cladding layer 231 formed on the top surface of the epitaxial substrate 21, an active layer 232 formed on the n-type cladding layer 231, a p-type cladding layer 233 formed on the active layer 232, and first and second electrodes 235, 234 formed on the n-type and p-type cladding layers 231, 233, respectively.

After formation of the p-type cladding layer 233, a portion of the p-type cladding layer 233 is removed together with a corresponding portion of the active layer 232 underlying the same, so as to expose a portion of the n-type cladding layer 231 for subsequent formation of the first electrode 235.

Subsequently, the epitaxial substrate 21 is thinned from the bottom surface of the epitaxial substrate 21. A reflecting layer 22 is then formed on the bottom surface of the thinned epitaxial substrate 21. Thereafter, a heat dissipating substrate 24 is formed on the reflecting layer 22. The heat dissipating substrate 24 has a thermal conductivity higher than that of the epitaxial substrate 21.

Preferably, a temporary substrate is formed on the p-type cladding layer 233 prior to the thinning operation of the epitaxial substrate 21. The temporary substrate is then removed from the p-type cladding layer 233 after formation of the heat dissipating unit 24. The temporary substrate may be made from glass and may be attached to the p-cladding layer 233 through an adhesive selected from the group consisting of wax, spin-on glass, photoresist, organic adhesive materials.

The epitaxial substrate 21 may be made from a material selected form the group consisting of GaP, GaAs, ZnO, and sapphire. Preferably, the epitaxial substrate 21 is made from sapphire. In addition, the epitaxial substrate 21 may be thinned by chemical mechanical polishing in such a manner that the thinned epitaxial substrate 21 has a thickness less than 50 μm. Alternatively, the epitaxial substrate 21 may be initially polished to a thickness of 80 μm to 120 μm. The polished epitaxial substrate 21 is then dry etched by using inductively coupled plasma (ICP) in such a manner that the thinned epitaxial substrate 21 has a thickness less than 50 μm.

In addition, the reflecting layer 22 may be made from a metal material selected from the group consisting of Au, Ag, Pt, Al, Ni, Cu, Ti, Ta, Cr, Pd, W, Mo, and alloys thereof. The reflecting layer 22 can be formed on the thinned epitaxial substrate 21 through physical vapor deposition techniques.

Alternatively, the reflecting layer 22 may include first and second dielectric layers. The first dielectric layer is bonded to the epitaxial substrate 21, and the heat dissipating substrate 24 is formed on the second dielectric layer. The first dielectric layer has a refractive index higher than that of the second dielectric layer. Preferably, each of the first and second dielectric layers is made from a dielectric material selected from the group consisting of ZnSe, MgF₂, SiO₂, Si, Si₃N₄, TiO₂, Ta₂O₅, HfO₂, ZrO₂, and blends thereof. For example, the reflecting layer 22 may be a combination of a ZnSe layer and a MgF₂ layer, a SiO₂ layer and a Si layer, a Si₃N₄ layer and a Si layer, a TiO₂ layer and a Si layer, a Ta₂O₅ layer and a Si layer, a HfO₂ layer and a SiO₂ layer, a Ta₂O₅ layer and a SiO₂ layer, a ZrO₂ layer and a SiO₂ layer, or a TiO₂ layer and a SiO₂ layer.

The heat dissipating substrate 24, which has a thermal conductivity higher than that of the epitaxial substrate 21, may be made from a metal material selected from the group consisting of Cu, Ag, Ni, Al, Ag, Mo, W and alloys thereof. Alternatively, the heat dissipating substrate may be made from a semiconductor material selected from the group consisting of Si and GaP. Preferably, the heat dissipating substrate 24 is formed on the reflecting layer 22 by bonding the heat dissipating substrate 24 to the reflecting layer 22 through an adhesive layer 25. The adhesive layer 25 may be made from conductive paste, wax, non-conductive paste, sol-gel SiO₂, polymers, photoresist, and low melting-point alloys.

After the heat dissipating substrate 24 is formed on the reflecting layer 22, the temporary substrate is removed from the p-type cladding layer 233. Preferably, the temporary substrate is removed from the p-type cladding layer 233 by etching or polishing techniques.

Alternatively, when the heat dissipating substrate 24 is made from metal, the heat dissipating substrate 24 may be formed on the reflecting layer 22 by electroplating techniques. A photoresist film is applied to the reflecting layer 22 first so as to form a pattern consisting of exposed regions and unexposed regions. The heat dissipating substrate 24 is then formed on the exposed regions of the patterned reflecting layer 22 by electroplating the metal material. Finally, the photoresist film is removed.

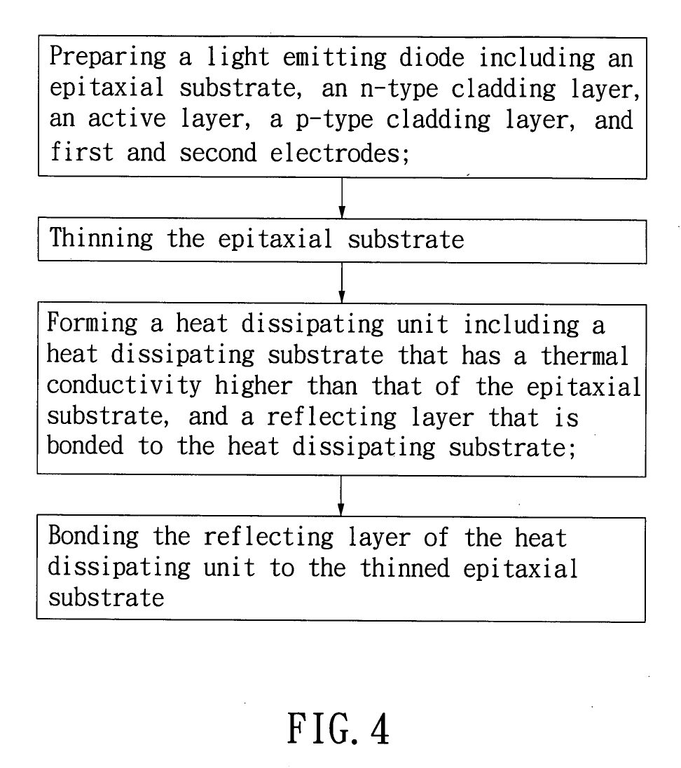

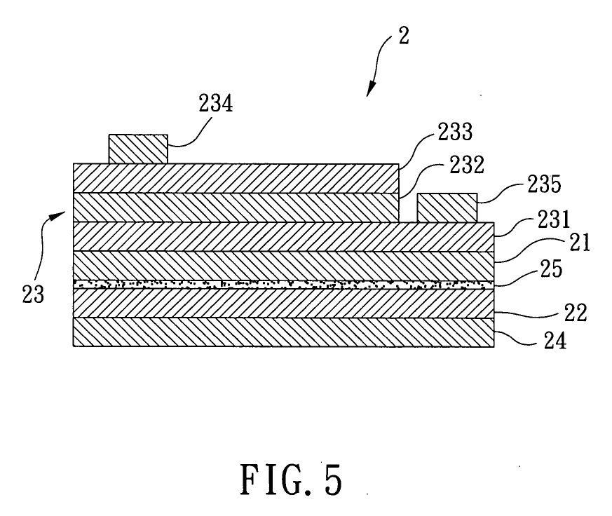

FIGS. 4 and 5 illustrate the second preferred embodiment of the method for manufacturing a light emitting device and the light emitting device thus formed. The second preferred embodiment of the present invention is similar to the first preferred embodiment of the present invention, except that after the epitaxial substrate 21 is thinned, a heat dissipating unit is formed and is subsequently bonded to the thinned epitaxial substrate 21 of the light emitting diode. The heat dissipating unit includes a heat dissipating substrate 24 having a thermal conductivity higher than that of the epitaxial substrate 21, and a reflecting layer 22 that is bonded to the heat dissipating substrate 24.

Preferably, a temporary substrate is further formed on the p-type cladding layer 233 prior to the thinning operation of the epitaxial substrate 21, and is removed from the p-type cladding layer 233 after bonding the heat dissipating unit to the thinned epitaxial substrate 21.

Preferably, the reflecting layer 22 of the heat dissipating unit is bonded to the thinned epitaxial substrate 21 through an adhesive layer 25. The adhesive layer 25 may be made from conductive paste, wax, non-conductive paste, sol-gel SiO₂, polymers, photoresist, and low melting-point alloys.

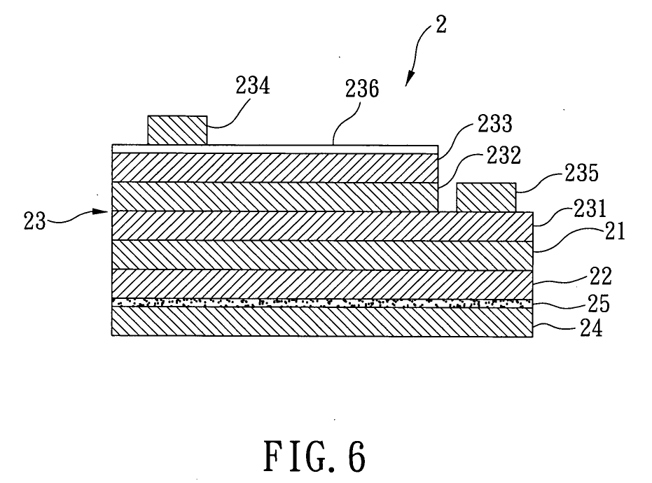

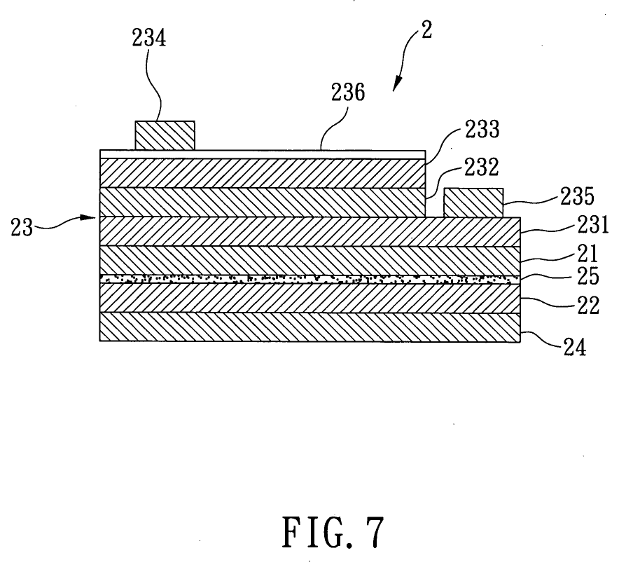

FIGS. 6 and 7 illustrate a structural modification of the light emitting devices 2 shown in FIGS. 3 and 5, respectively, wherein each of the light emitting devices 2 of FIGS. 3 and 5 further includes a transparent conductive layer 236 formed on the p-type cladding layer 233. The second electrode 234 is formed on and is connected to the p-type cladding layer 233 through the transparent conductive layer 236. Preferably, the transparent conductive layer 236 is made from a material selected from the group consisting of NiAu, indium tin oxide, and zinc oxide.

With the inclusion of the transparent conductive layer 236 in the light emitting device of the present invention, a uniform current passing through the light emitting device can be achieved, and the output power of the light emitting device 2 can be enhanced.

According to this invention, an improved efficiency in heat dissipation is achieved by reducing the thickness of the epitaxial substrate 21. In addition, formation of the reflecting layer 22 on the epitaxial substrate 21 can be conducted by bonding or electroplating techniques at a temperature less than 300° C., and bonding of the heat dissipating unit can be conducted at a temperature less than 300° C. so that good epitaxial crystal quality of the light emitting device 2 can be achieved. Therefore, the method for manufacturing the light emitting device of this invention and the light emitting device manufactured therefrom are suitable for application to the fabrication of blue or UV light emitting diodes having a large light-emitting area and a high light-emitting efficiency.

While the present invention has been described in connection with what is considered the most practical and preferred embodiments, it is understood that this invention is not limited to the disclosed embodiments but is intended to cover various arrangements included within the spirit and scope of the broadest interpretation and equivalent arrangements.

We claim:

1. A method for manufacturing a light emitting device, comprising:
(a) preparing a light emitting diode including an epitaxial substrate having a top surface and a bottom surface opposite to the top surface, an n-type cladding layer formed on the top surface of the epitaxial substrate, an active layer formed on the n-type cladding layer, a p-type cladding layer formed on the active layer, and first and second electrodes formed on the n-type and p-type cladding layers, respectively;
(b) thinning the epitaxial substrate from the bottom surface of the epitaxial substrate;
(c) forming a reflecting layer on the bottom surface of the thinned epitaxial substrate; and
(d) forming a heat dissipating substrate, which has a thermal conductivity higher than that of the epitaxial substrate, on the reflecting layer.

2. The method as claimed in claim 1, further comprising forming a temporary substrate on the p-type cladding layer prior to the thinning operation of the epitaxial substrate, and removing the temporary substrate from the p-type cladding layer after formation of the heat dissipating substrate.

3. The method as claimed in claim 1, wherein the epitaxial substrate is made from a material selected form the group consisting of GaP, GaAs, ZnO, and sapphire.

4. The method as claimed in claim 1, wherein, in step (b), the epitaxial substrate is thinned by chemical mechanical polishing in such a manner that the thinned epitaxial substrate has a thickness less than 50 μm.

5. The method as claimed in claim 1, wherein, in step (b), the epitaxial substrate is thinned by polishing and then dry etching in such a manner that the thinned epitaxial substrate has a thickness less than 50 μm.

6. The method as claimed in claim 1, wherein the reflecting layer is made from a metal material selected from the group consisting of Au, Ag, Pt, Al, Ni, Cu, Ti, Ta, Cr, Pd, W, Mo, and alloys thereof.

7. The method as claimed in claim 1, wherein the reflecting layer includes first and second dielectric layers, the first dielectric layer being bonded to the epitaxial substrate, the heat dissipating substrate being formed on the second dielectric layer, the first dielectric layer having a refractive index higher than that of the second dielectric layer, each of the first and second dielectric layers being made from a dielectric material selected from the group consisting of ZnSe, MgF₂, SiO₂, Si, Si₃N₄, TiO₂, Ta₂O₅, HfO₂, ZrO₂, and blends thereof.

8. The method as claimed in claim 1, wherein the heat dissipating substrate is made from a metal material selected from the group consisting of Cu, Ag, Ni, Al, Ag, Mo, W and alloys thereof.

9. The method as claimed in claim 1, wherein the heat dissipating substrate is made from a semiconductor material selected from the group consisting of Si and GaP.

10. A method for manufacturing a light emitting device, comprising:
(a) preparing a light emitting diode including an epitaxial substrate having a top surface and a bottom surface opposite to the top surface, an n-type cladding layer formed on the top surface of the epitaxial substrate, an active layer formed on the n-type cladding layer, a p-type cladding layer formed on the active layer, and first and second electrodes formed on the n-type and p-type cladding layers, respectively;
(b) thinning the epitaxial substrate from the bottom surface of the epitaxial substrate;
(c) forming a heat dissipating unit including a heat dissipating substrate that has a thermal conductivity higher than that of the epitaxial substrate, and a reflecting layer that is bonded to the heat dissipating substrate; and
(d) bonding the reflecting layer of the heat dissipating unit to the thinned epitaxial substrate of the light emitting diode.

11. The method as claimed in claim 10, further comprising forming a temporary substrate on the p-type cladding layer prior to the thinning operation of the epitaxial substrate, and removing the temporary substrate from the p-type cladding layer after bonding of the heat dissipating unit to the thinned epitaxial substrate.

12. The method as claimed in claim 10, wherein the epitaxial substrate is made from a material selected form the group consisting of GaP, GaAs, ZnO, and sapphire.

13. The method as claimed in claim 10, wherein, in step (b), the epitaxial substrate is thinned by chemical mechanical polishing in such a manner that the thinned epitaxial substrate has a thickness less than 50 μm.

14. The method as claimed in claim 10, wherein, in step (b), the epitaxial substrate is thinned by polishing and then dry etching in such a manner that the thinned epitaxial substrate has a thickness less than 50 μm.

15. The method as claimed in claim 10, wherein the reflecting layer is made from a metal material selected from the group consisting of Au, Ag, Pt, Al, Ni, Cu, Ti, Ta, Cr, Pd, W, Mo, and alloys thereof.

16. The method as claimed in claim 10, wherein the reflecting layer includes first and second dielectric layers, the first dielectric layer being bonded to the epitaxial substrate, the heat dissipating substrate being formed on the second dielectric layer, the first dielectric layer having a refractive index higher than that of the second dielectric layer, each of the first and second dielectric layers being made from a material selected from the group consisting of ZnSe, MgF₂, SiO₂, Si, Si₃N₄, TiO₂, Ta₂O₅, HfO₂, ZrO₂, and blends thereof.

17. The method as claimed in claim 10, wherein the heat dissipating substrate is made from a metal material selected from the group consisting of Cu, Ag, Ni, Al, Ag, Mo, W and alloys thereof.

18. The method as claimed in claim 10, wherein the heat dissipating substrate is made from a semiconductor material selected from the group consisting of Si and GaP.

19. A light emitting device, comprising:
a heat dissipating substrate;
a reflecting layer bonded to said heat dissipating substrate; and
a light emitting diode bonded to said reflecting layer, said light emitting diode including an epitaxial substrate having a top surface and a bottom surface opposite to said top surface, an n-type cladding layer formed on said top surface of said epitaxial substrate, an active layer formed on said n-type cladding layer, a p-type cladding layer formed on said active layer, and first and second electrodes formed on said n-type and p-type cladding layers, respectively;
wherein said reflecting layer is bonded to said bottom surface of said epitaxial substrate; and
wherein said heat dissipating substrate has a thermal conductivity higher than that of said epitaxial substrate.

20. The light emitting device as claimed in claim 19, wherein said epitaxial substrate is made from a material selected form the group consisting of GaP, GaAs, ZnO, and sapphire.

21. The light emitting device as claimed in claim 19, wherein said epitaxial substrate has a thickness less than 50 μm.

22. The light emitting device as claimed in claim 19, wherein said reflecting layer is made from a metal material selected from the group consisting of Au, Ag, Pt, Al, Ni, Cu, Ti, Ta, Cr, Pd, W, Mo, and alloys thereof.

23. The light emitting device as claimed in claim 19, wherein said reflecting layer includes first and second dielectric layers, said first dielectric layer being bonded to said epitaxial substrate, said heat dissipating substrate being formed on said second dielectric layer, said first dielectric layer having a refractive index higher than that of said second dielectric layer, each of said first and second dielectric layers being made from a dielectric material selected from the group consisting of ZnSe, MgF₂, SiO₂, Si, Si₃N₄, TiO₂, Ta₂O₅, HfO₂, ZrO₂, and blends thereof.

24. The light emitting device as claimed in claim 19, wherein said heat dissipating substrate is made from a metal material selected from the group consisting of Cu, Ag, Ni, Al, Ag, Mo, W and alloys thereof.

25. The light emitting device as claimed in claim 19, wherein said heat dissipating substrate is made from a semiconductor material selected from the group consisting of Si and GaP.

26. The light emitting device as claim in claim 19, wherein said reflecting layer is bonded to said heat dissipating substrate through an adhesive layer interposed therebetween.

27. The light emitting device as claim in claim 19, wherein said reflecting layer is bonded to said bottom surface of said epitaxial substrate through an adhesive layer interposed therebetween.
